(19) United States
(12) Patent Application Publication
(10) Pub. No.: US 2016/0048328 A1
(43) Pub. Date: Feb. 18, 2016

(54) MEMORY SYSTEM

(71) Applicant: Kabushiki Kaisha Toshiba, Tokyo (JP)

(72) Inventor: Kazuya Kitsunai, Fujisawa Kanagawa (JP)

(21) Appl. No.: 14/579,391

(22) Filed: Dec. 22, 2014

Related U.S. Application Data
(60) Provisional application No. 62/036,357, filed on Aug. 12, 2014.

(51) Int. Cl. G06F 3/06; G06F 12/06; G06F 12/02; G11C 7/10

(52) U.S. Cl. CPC G06F 3/061; G06F 3/0688; G06F 3/0655; G11C 7/1072; G06F 12/0638; G06F 12/0246; G06F 2212/205; G06F 2212/7201

(57) ABSTRACT

A memory system in the embodiment includes an address conversion table including a first conversion table and a second conversion table, a management table storing the first information that indicates whether the second conversion table is a first state, and a controller. In the case where determining based on the first information that the second conversion table written from a volatile second memory to a nonvolatile first memory is in the first state, the controller updates the first conversion table and releases the storage area of the second conversion table used for the writing from the second memory.

### CROSS-REFERENCE TO RELATED APPLICATIONS

This application is based upon and claims the benefit of priority from U.S. Provisional Application No. 62/036,357, filed on Aug. 12, 2014; the entire contents of which are incorporated herein by reference.

### FIELD

The present embodiment generally relates to a memory system.

### BACKGROUND

A memory system including a semiconductor storage device uses an address conversion table for mapping the logical address designated in the Read/Write request from a host device onto an arbitrary physical address. Especially, a high-capacity semiconductor storage device uses a multistage address conversion table to efficiently store an address conversion table. It is preferable in such a memory system to suppress the decrease in the performance when the table is updated.

### BRIEF DESCRIPTION OF THE DRAWINGS

FIG. 1 is a block diagram of an exemplary configuration of a memory system according to an embodiment;

FIG. 2 is an explanatory diagram of the configuration of an address conversion table;

FIG. 3 is an explanatory diagram of the operation of a controller;

FIG. 4 is a flowchart of the procedures of a process for updating a 1st Table;

FIG. 5 is a schematic diagram of the configuration of a cache management table;

FIG. 6 is a flowchart of the procedures of a process for updating a physical address;

FIG. 7 is a flowchart of the procedures of a process for fixation of a 2nd Table;

FIG. 8 is a flowchart of the procedures of a process for updating cache management information;

FIG. 9 is an explanatory diagram of the order of the 2nd Tables to be written from the cache memory into a nonvolatile memory; and

FIG. 10 is an explanatory diagram of the variations in the space area of the cache memory.

### DETAILED DESCRIPTION

The present embodiment provides a memory system. The memory system includes an address conversion table in which a logical address of user data transmitted from a host device is linked to a physical address indicating a storage position of the user data. The address conversion table includes a first conversion table and a second conversion table storing the physical address. A storage position of the second conversion table is stored in the first conversion table. The memory system includes: a management table that stores first information indicating whether the second conversion table is the latest for each of the second conversion tables; a first memory that is nonvolatile and stores the user data, the address conversion table, and the management table; a second memory that is volatile; and a controller. The controller reads the second conversion table corresponding to the user data from the first memory into the second memory, and updates the second conversion table in the second memory after the user data is transmitted from the host device. The controller writes the updated second conversion table from the second memory into the first memory. In the case where updating the second conversion table corresponding to new user data while the writing, the controller copies the updated second conversion table in the second memory and updates the second conversion table corresponding to the new user data. The controller performs the reading, the writing, and the copying. The controller determines, after the writing is performed, whether the second conversion table is in a first state. The determination process is performed based on the first information. In the case where the second conversion table is determined to be in the first state, the controller updates the first conversion table, and releases a storage area of the second conversion table used for the writing.

The memory system according to an embodiment will be described in detail hereinafter with reference to the appended drawings. Note that the present invention is not limited to the embodiment.

### Embodiment

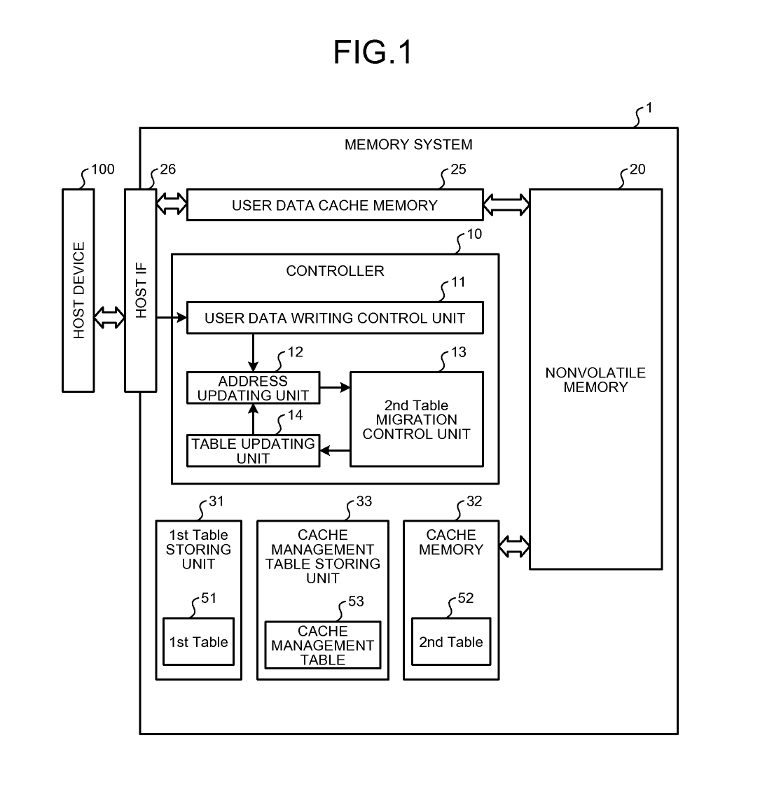

FIG. 1 is a block diagram of an exemplary configuration of a memory system according to the embodiment. A memory system 1 is a system that includes a storage device such as a semiconductor storage device, and is connected to a host device 100. The memory system 1 receives a Read/Write request transmitted from the host device 100 and performs the Read/Write of the data according to the Read/Write request.

The memory system 1 uses a multistage address conversion table to map the logical address designated in the Read/Write request from the host device 100 onto the physical address. The multistage address conversion table in the present embodiment includes a 1st Table 51 storing the logical address and a 2nd Table 52 storing the physical address.

The memory system 1 in the present embodiment sets a flag indicating whether the 2nd Table 52 is the latest (first state) for each 2nd Table 52 to update the 1st Table 51 when the latest 2nd Table 52 is written from a cache memory 32 to a nonvolatile memory 20. Then, the memory system 1 releases, from the cache memory 32, the 2nd Table 52 in the cache memory 32 that has been written from the cache memory 32 to the nonvolatile memory 20.

First, the memory system 1 in the present embodiment stores the flag indicating whether the 2nd Table 52 is the latest, for example, in a Static Random Access Memory (SRAM) accessible faster than a Dynamic Random Access Memory (DRAM). The latest 2nd Table 52 is a 2nd Table 52 on which the latest physical address in the latest status is reflected when a plurality of 2nd Tables 52 exists, for example, due to a copying process.

The physical address of the user data of which Write has finally been transmitted to the logical address is recorded in the latest 2nd Table 52. In other words, among the 2nd Tables 52, the latest 2nd Table 52 includes the physical address in which the user data of which Write has finally been transmitted to the logical address designated in the Read/Write request is recorded.

For example, on the assumption that three Write request have been transmitted from the host device 100 to the logical address=A, the physical addresses are recorded as the following (a) to (c).
(a) At the first Write, the user data is recorded in the nonvolatile memory 20 of which physical address=1. The physical address=1 is recorded in a first 2nd Table 52.
(b) At the second Write, the user data is recorded in the nonvolatile memory 20 of which physical address=2. The physical address=2 is recorded in a second 2nd Table 52.
(c) At the third Write, the user data is recorded in the nonvolatile memory 20 of which physical address=3. The physical address=3 is recorded in a third 2nd Table 52.

The latest 2nd Table 52 is the third 2nd Table 52 in that case.

Note that, in the present embodiment, the update of the 1st Table 51 is sometimes referred to as a 1st table update, and the update of the physical address in the 2nd Table 52 is sometimes referred to as a physical address update. In the 1st table update, the address of the 2nd Table 52 stored in the 1st Table 51 is updated. In the physical address update, the physical address stored in the 2nd Table 52 is updated.

The memory system 1 includes a controller 10, a nonvolatile memory 20, a user data cache memory 25, and a host IF 26. The memory system 1 further includes a 1st Table storing unit 31, a cache management table storing unit 33, and a cache memory 32.

The host IF 26 is a communication interface connected to the host device 100. The host IF 26 is connected to the user data cache memory 25 and the controller 10.

The nonvolatile memory 20 is connected to the user data cache memory 25 and the cache memory 32. Although not illustrated in FIG. 1, the nonvolatile memory 20 is connected to the controller 10, the 1st Table storing unit 31, and the cache management table storing unit 33. The nonvolatile memory 20 is a memory such as a NAND Flash Read Only Memory (ROM), stores the user data, the address conversion table and the like.

The logical address of the user data transmitted from the host device 100 is linked to the physical address indicating the storage position of the user data in the address conversion table using the 1st Table 51 and the 2nd Table 52.

When the host device 100 sends a Write request, the user data cache memory 25 buffers the user data to be transmitted from the host device 100 to the nonvolatile memory 20.

When the host device 100 sends a Read request, the user data cache memory 25 buffers the user data to be transmitted from the nonvolatile memory 20 to the host device 100. The user data cache memory 25 is, for example, an SRAM.

The 1st Table storing unit 31 stores the 1st Table 51 read from the nonvolatile memory 20. The 1st Table 51 is relatively large in size. Accordingly, the 1st Table storing unit 31 is, for example, a DRAM that has a larger capacity and is accessed at a low rate than an SRAM.

The cache memory 32 is a memory that stores the 2nd Table 52 read from the nonvolatile memory 20. The cache memory 32 is, for example, an SRAM that has a smaller capacity and is accessed at a higher rate than a DRAM.

The cache management table storing unit 33 stores the cache management table 53 read from the nonvolatile memory 20. The cache management table 53 is a table that manages the cache memory 32. The cache management table storing unit 33 is, for example, an SRAM that has a smaller capacity and is accessed at a higher rate than a DRAM.

The controller 10 controls the nonvolatile memory 20, the user data cache memory 25, the host IF 26, the 1st Table storing unit 31, the cache management table storing unit 33, and the cache memory 32.

The controller 10 includes the user data writing control unit 11, the address updating unit 12, the 2nd table migration control unit 13, and the table updating unit 14. The user data writing control unit 11 controls the writing of the user data, for example, into the nonvolatile memory 20.

The user data writing control unit 11 transmits an address updating request of the physical address to the address updating unit 12 after the completion of the writing of the user data. The physical address updating request is for updating the physical address of the destination for writing the user data, and includes the information about the logical address to be updated and the physical address of the destination for writing the data.

When receiving the physical address updating request, the address updating unit 12 transmits a request for reading the 2nd Table 52 into the cache memory 32 or a request for copying the 2nd Table 52 in the cache memory 32 to the 2nd table migration control unit 13.

The address updating unit 12 updates the physical address of the 2nd Table 52 in the cache memory 32 based on the physical address updating request. After updating the physical address, the address updating unit 12 transmits a request for writing the 2nd Table 52 into the nonvolatile memory 20 to the 2nd table migration control unit 13 at a predetermined timing.

Note that, in the present embodiment, copying the data such as the 2nd Table 52 from the nonvolatile memory 20 onto the cache memory 32 is referred to as reading, and copying the data such as the 2nd Table 52 from the cache memory 32 onto the nonvolatile memory 20 is referred to as writing.

When receiving the request for reading the 2nd Table 52, the 2nd table migration control unit 13 reads the 2nd Table 52 in the nonvolatile memory 20 into the cache memory 32. Alternatively, when receiving the request for copying the 2nd Table 52, the 2nd table migration control unit 13 copies the latest 2nd Table 52 in the cache memory 32. Alternatively, when receiving the request for writing the 2nd Table 52, the 2nd table migration control unit 13 writes the 2nd Table 52 into the nonvolatile memory 20.

When receiving a reading completion notification or a copying completion notification from the 2nd table migration control unit 13, the table updating unit 14 updates the 1st Table 51 using the address in the cache memory 32 in which the 2nd Table 52 is stored.

Alternatively, when receiving a writing completion notification from the 2nd table migration control unit 13 and only when the 2nd Table 52 written into the nonvolatile memory 20 is the latest 2nd Table 52, the table updating unit 14 updates the 1st Table 51 using the address of the 2nd Table 52 in the nonvolatile memory 20.

When receiving the data to be written from the host device 100, the memory system 1 buffers the data to be written in the user data cache memory 25 to write the data into the nonvolatile memory 20. This updates the 1st Table 51. After that, the 2nd Table 52 is updated. Specifically, the address of the 2nd Table 52 is updated in the 1st Table 51. After that, the physical address is updated in the 2nd Table 52.

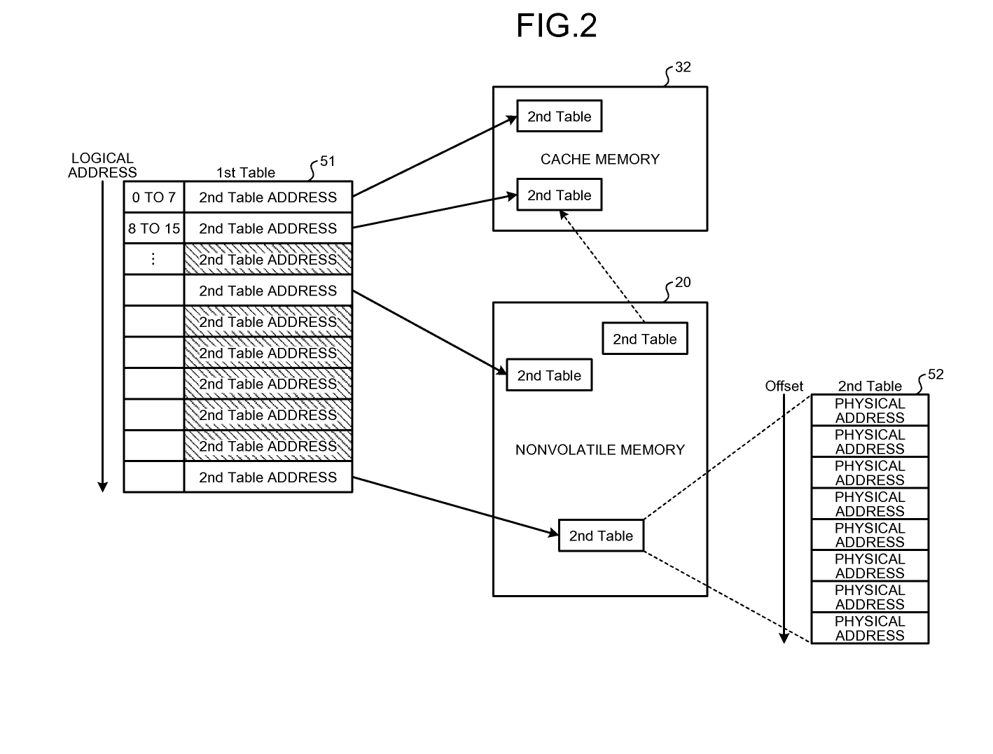

The configuration of the address conversion table will be described hereinafter. FIG. 2 is an explanatory diagram of the configuration of the address conversion table. The address conversion table includes the 1st Table 51 and the 2nd Table 52. In the 1st Table 51, the logical address designated by the host device 100 is linked to the address in which the 2nd Table 52 is stored.

A plurality of addresses of the 2nd Tables 52 is stored in the 1st Table 51. The 2nd Tables 52 are stored in the nonvolatile memory 20 or the cache memory 32. Thus, an address in the nonvolatile memory 20 or an address in the cache memory 32 is stored as the address of the 2nd Table 52 in the 1st Table 51.

For example, when a 2nd Table 52 is allocated to each set of eight logical addresses in the 1st Table 51, eight physical addresses are stored in each 2nd Table 52. In that case, the number of the remainder when the logical addresses are divided by eight corresponds to the offset of the data storage position in the 2nd Table 52.

When the physical address is updated, the 2nd Table 52 is read from the nonvolatile memory 20 into the cache memory 32. Alternatively, after the physical address is updated, the 2nd Table 52 is written from the cache memory 32 to the nonvolatile memory 20. In such a case, when the 2nd Tables 52 are collectively written into a plurality of NAND physical pages into which the 2nd Tables 52 can be written in parallel while the 2nd Tables 52 are written into the nonvolatile memory 20, this increases the area unavailable due to the update of the physical addresses during the writing. In light of the foregoing, the 2nd Tables 52 are written not in parallel, but in a smaller unit than the parallel writing.

When the 2nd Table 52 is read from the nonvolatile memory 20 into the cache memory 32, a 1st table update that is the update of the address of the 2nd Table 52 in the 1st Table 51 is performed in the memory system 1.

When the user data is written into the nonvolatile memory 20, a physical address update that is the update of the physical address in the 2nd Table 52 is performed in the memory system 1. The physical address is the physical address of the user data in the nonvolatile memory 20.

When the 2nd Table 52 is written from the cache memory 32 into the nonvolatile memory 20 and only when the written 2nd Table 52 is the latest, the 1st table update is performed in the memory system 1. In the present embodiment, it is determined, using a flag indicating whether the 2nd Table 52 is the latest, whether each of the 2nd Tables 52 is the latest.

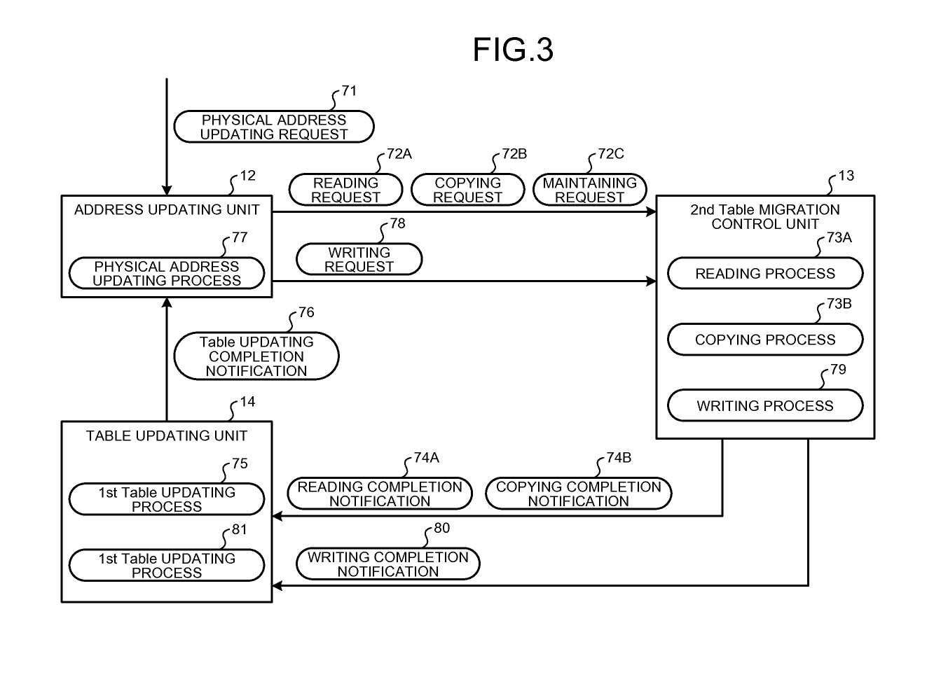

FIG. 3 is an explanatory diagram of the operation of the controller. When receiving a physical address updating request 71 from the user data writing control unit 11, the address updating unit 12 determines based on the 1st Table 51 whether the latest 2nd Table 52 corresponding to the user data is stored in the nonvolatile memory 20. The logical address of the user data to be written is added to the physical address updating request 71.

When receiving the physical address updating request 71 and when the latest 2nd Table 52 corresponding to the user data is stored in the nonvolatile memory 20, the address updating unit 12 transmits a reading request 72A for reading the latest 2nd Table 52 into the cache memory 32 to the 2nd table migration control unit 13. The address of the latest 2nd Table 52 in the nonvolatile memory 20 is added to the reading request 72A.

When the address updating unit 12 receives the physical address updating request 71 and when the latest 2nd Table 52 is in process of being written from the cache memory 32 into the nonvolatile memory 20, the address updating unit 12 transmits a copying request 72B for copying the 2nd Table 52 in the cache memory 32 to the 2nd table migration control unit 13. The address of the latest 2nd Table 52 in the cache memory 32 is added to the copying request 72B.

When the address updating unit 12 receives the physical address updating request 71, and when the latest 2nd Table 52 is stored in the cache memory 32 and is not in process of being written into the nonvolatile memory 20, the address updating unit 12 transmits a maintaining request 72C for maintaining the 2nd Table 52 in the cache memory 32 to the 2nd table migration control unit 13. The address of the latest 2nd Table 52 in the cache memory 32 is added to the maintaining request 72C.

When receiving the reading request 72A or copying request 72B for the 2nd Table 52, the 2nd table migration control unit 13 stores the latest 2nd Table 52 in the cache memory 32. Specifically, when receiving the reading request 72A for the 2nd Table 52, the 2nd table migration control unit 13 performs a reading process 73A for reading the latest 2nd Table 52 in the nonvolatile memory 20 into the cache memory 32. At that time, the 2nd table migration control unit 13 performs the reading process 73A based on the address of the latest 2nd Table 52 added to the reading request 72A. Performing the reading process 73A causes the 2nd Table 52 read into the cache memory 32 to be the latest 2nd Table 52.

When receiving the copying request 72B for the 2nd Table 52, the 2nd table migration control unit 13 performs the copying process 73B for copying the latest 2nd Table 52 in the cache memory 32. At that time, the 2nd table migration control unit 13 performs the copying process 73B based on the address of the latest 2nd Table 52 added to the copying request 72B. Performing the copying process 73B causes the copied 2nd Table 52 to be the latest 2nd Table 52. Alternatively, when receiving the maintaining request 72C for the 2nd Table 52, the 2nd table migration control unit 13 does not copy the latest 2nd Table 52 in the cache memory 32, but maintains the latest 2nd Table 52 without any change.

When reading the 2nd Table 52 into the cache memory 32, the 2nd table migration control unit 13 transmits a reading completion notification 74A to the table updating unit 14 after the completion of the reading. When copying the 2nd Table 52 in the cache memory 32, the 2nd table migration control unit 13 transmits a copying completion notification 74B to the table updating unit 14 after the completion of the copying. The reading completion notification 74A and the copying completion notification 74B are for causing the table updating unit 14 to perform the 1st table update. The address of the latest 2nd Table 52 in the cache memory 32 is added to the notifications.

When receiving the reading completion notification 74A or the copying completion notification 74B, the table updating unit 14 performs a 1st Table updating process 75 using the address in the cache memory 32 in which the 2nd Table 52 is stored. After performing the 1st Table updating process 75, the table updating unit 14 transmits a table updating completion notification 76 indicating the completion of the update of the 1st Table 51 to the address updating unit 12.

When receiving the table updating completion notification 76 from the table updating unit 14, the address updating unit 12 performs a physical address updating process 77 for the 2nd Table 52 in the cache memory 32 based on the physical address updating request 71. In that case, the 2nd Table 52 for which the physical address updating process 77 is performed is the 2nd Table 52 that has become the latest by being read into the cache memory 32, or the 2nd Table 52 that has become the latest by being copied in the cache memory 32.

When transmitting the maintaining request 72C to the nonvolatile memory 20, the address updating unit 12 performs the physical address updating process 77 for the 2nd Table 52 in the cache memory 32 based on the physical address updating request 71. In that case, the 2nd Table 52 for which the physical address updating process 77 is performed is the 2nd Table 52 that is maintained without being copied in the cache memory 32.

After performing the physical address updating process 77 for the latest 2nd Table 52, the address updating unit 12 transmits a writing request 78 for writing the 2nd Table 52 into the nonvolatile memory 20 to the 2nd table migration control unit 13 at a predetermined timing. For example, when the amount of the space in the cache memory 32 is less than a predetermined amount, the address updating unit 12 transmits the writing request 78 for writing the 2nd Table 52 into the nonvolatile memory 20 to the 2nd table migration control unit 13. The address of the latest 2nd Table 52 in the cache memory 32 is added to the writing request 78.

The 2nd table migration control unit 13 performs a writing process 79 that is a process for writing the 2nd Table 52 into the nonvolatile memory 20 based on the writing request 78. When writing the 2nd Table 52 into the nonvolatile memory 20, the 2nd table migration control unit 13 transmits a writing completion notification 80 to the table updating unit 14 after the completion of the writing. The writing completion notification 80 is a notification for causing the table updating unit 14 to perform the 1st table update. The address of the written 2nd Table 52 in the nonvolatile memory 20 is added the notification.

Note that the processes for writing the 2nd Table 52 into the nonvolatile memory 20 are not necessarily completed in order of reception of the writing requests. Accordingly, the timing in which the 1st table is updated after the request for writing the 2nd Table 52 into the nonvolatile memory 20 varies depending on the state of the memory system 1.

When the table updating unit 14 receives the writing completion notification 80 and only when the 2nd Table 52 written into the nonvolatile memory 20 is the latest in the cache memory 32, the table updating unit 14 updates the 1st Table 51 using the address of the written 2nd Table 52 in the nonvolatile memory 20. In other words, when receiving the writing completion notification 80 and only when the 2nd Table 52 written into the nonvolatile memory 20 reflects the latest contents, the table updating unit 14 performs a 1st table updating process 81.

The table updating unit 14 in the present embodiment determines, based on the flag indicating whether the 2nd Table 52 is the latest, whether each of the 2nd Tables 52 in the nonvolatile memory 20 is the latest. Only when the 2nd Table 52 is the latest, the table updating unit 14 updates the 1st Table 51.

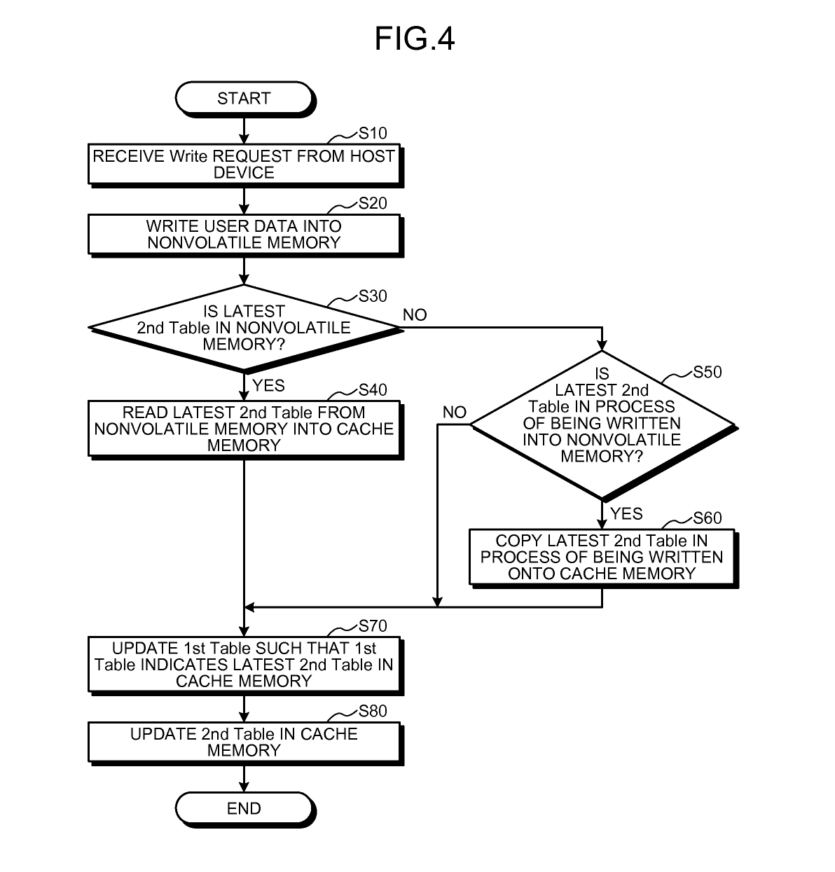

FIG. 4 is a flowchart of the procedures in the process for updating the 1st Table. When the host device 100 transmits a Write request for user data and the user data, the memory system 1 receives the Write request and the user data from the host device 100 (step S10).

As a result, the user data writing control unit 11 stores the user data in the nonvolatile memory 20 (step S20). After that, the address updating unit 12 determines whether the 2nd Table 52 in which the physical address of the user data is to be stored is stored in the nonvolatile memory 20. In other words, it is determined whether the latest 2nd Table 52 is stored in the nonvolatile memory 20 (step S30).

When the latest 2nd Table 52 is stored in the nonvolatile memory 20 (Yes in step S30), the 2nd table migration control unit 13 reads the latest 2nd Table 52 from the nonvolatile memory 20 into the cache memory 32 (step S40).

When the latest 2nd Table 52 is stored in the cache memory 32 (No in step S30), the address updating unit 12 determines whether the latest 2nd Table 52 is in process of being written into the nonvolatile memory 20 (step S50).

When the latest 2nd Table 52 is not in process of being written from the cache memory 32 into the nonvolatile memory 20 (No in step S50), the 2nd table migration control unit 13 maintains the latest 2nd Table 52 in the cache memory 32 without any change.

On the other hand, when the latest 2nd Table 52 is in process of being written from the cache memory 32 into the nonvolatile memory 20 (Yes in step S50), the 2nd table migration control unit 13 copies the latest 2nd Table 52 in process of being written in the cache memory 32 (step S60).

For example, when the memory system 1 receives a Write request from the host device 100 before the completion of the writing of the latest 2nd Table 52 from the cache memory 32 into the nonvolatile memory 20, the latest 2nd Table 52 is stored in the cache memory 32. In that case, the latest 2nd Table 52 is copied in the cache memory 32.

After the latest 2nd Table 52 is read, copied, or maintained, the table updating unit 14 updates the 1st Table 51 such that the 1st Table 51 indicates the latest 2nd Table 52 in the cache memory 32 (step S70).

The cache memory 32 sometimes stores a plurality of 2nd Tables 52. Even in such a case, the table updating unit 14 updates the 1st Table 51 such that the 1st Table 51 indicates the latest 2nd Table 52 in the 2nd Tables 52. Specifically, every time a 2nd Table 52 is copied, the table updating unit 14 updates the 1st Table 51 such that the 1st Table 51 indicates the latest 2nd Table 52.

After the 1st Table 51 is updated, the address updating unit 12 updates the 2nd Table 52 in the cache memory 32 (step S80). The 2nd Table 52 is updated in the memory system 1 every time the 1st Table 51 is updated. Accordingly, the 2nd Table 52 is updated in the memory system 1 every time the 1st Table 51 is copied.

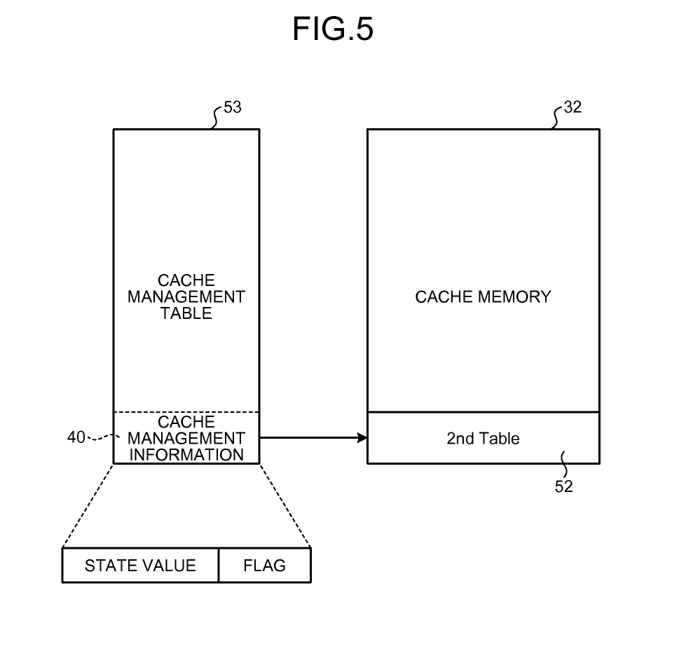

FIG. 5 is a schematic diagram of the configuration of the cache management table. The cache memory 32 stores the 2nd Table 52. Cache management information 40 is stored in the cache management table 53. The cache management information 40 is the information about the usage state of the cache memory 32.

In the memory system 1, the storage position of the cache management information 40 in the cache management table 53 is linked to the storage position of the 2nd Table 52 in the cache memory 32. For example, the cache management information 40 about the 2nd Table 52 stored in the mth (the m is a natural number) address area in the cache memory 32 is stored in the mth address area in the cache management table 53.

This facilitates the search for the cache management information 40 corresponding to the 2nd Table 52. Note that the identification information can be added to the cache management information 40 and 2nd Table 52 so as to link the cache management information 40 to the 2nd Table 52 using the identification information.

The cache management information 40 includes the state value of the 2nd Table 52 in the cache memory 32 and a flag. The flag that is ON indicates that the 2nd Table 52 stored in the cache area of the cache memory 32 is the latest. The value indicating one of the following three states (1) to (3) is stored in the state value.
(1) Empty: the state in which the cache area is not in use (free state)
(2) Dirty: the state in which the cache area is in use
(3) Writing: the state in which the 2nd Table 52 is in process of being written into the nonvolatile memory 20

When the state value is the value indicating the Empty, the 2nd Table 52 is stored in the nonvolatile memory 20. When the state value is the value indicating the Dirty, the 2nd Table 52 is stored in the cache memory 32 and is not written into the nonvolatile memory 20 yet. When the state value is the value indicating the Writing, the 2nd Table 52 is stored in the cache memory 32 and is in process of being written into the nonvolatile memory 20.

The cache management information 40 is stored in a memory such as an SRAM that is accessed at a high rate in the present embodiment. Thus, in the fixation of the updated contents of the address conversion table, the flag can be accessed in a short time.

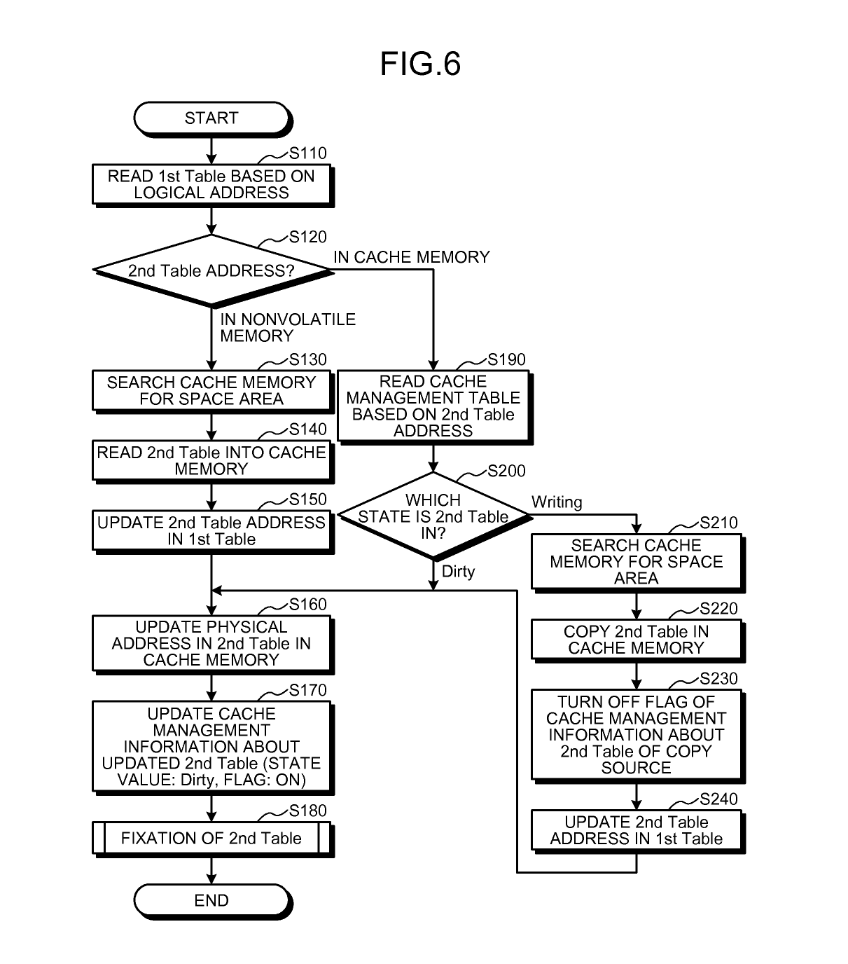

FIG. 6 is a flowchart of the procedures in the process for updating the physical address. When receiving the physical address updating request 71 from the user data writing control unit 11, the address updating unit 12 searches the 1st Table 51 for the address of the 2nd Table 52. Specifically, the address updating unit 12 reads the 1st Table 51 based on the logical address added to the physical address updating request 71 so as to search the 1st Table 51 for the address of the 2nd Table 52 (step S110).

The address updating unit 12 determines based on the address of the 2nd Table 52 that is the search result whether the 2nd Table 52 is stored in the nonvolatile memory 20. In other words, the address updating unit 12 determines whether the address of the 2nd Table 52 that the 1st Table 51 indicates is in the nonvolatile memory 20 or in the cache memory 32 (step S120). Note that the address updating unit 12 can determine based on the state value in the cache management information 40 whether the latest 2nd Table 52 is stored in the nonvolatile memory 20.

When the address of the 2nd Table 52 that the 1st Table 51 indicates is in the nonvolatile memory 20 (in the nonvolatile memory in step S120), the address updating unit 12 transmits the reading request 72A to the 2nd table migration control unit 13. Note that, when the state value is the Empty, the address updating unit 12 can transmit the reading request 72A to the 2nd table migration control unit 13.

This causes the 2nd table migration control unit 13 to search the cache memory 32 for the space area (step S130) to read the 2nd Table 52 into the space area of the cache memory 32 from the nonvolatile memory 20 (step S140). The process for reading the 2nd Table 52 is the reading process 73A.

The table updating unit 14 updates the address of the 2nd Table 52 in the 1st Table 51 (step S150). Specifically, the table updating unit 14 updates the address of the 2nd Table in the 1st Table 51 from the address in the nonvolatile memory 20 to the address in the cache memory 32. The process for updating the 1st Table 51 is the 1st Table updating process 75.

The address updating unit 12 updates the physical address in the 2nd Table 52 in the cache memory 32 (step S160). The process for updating the physical address is the physical address updating process 77.

After the 2nd Table 52 is updated, the table updating unit 14 updates the cache management information 40 about the updated 2nd Table 52. Specifically, the table updating unit 14 sets the state value in the cache management information 40 at the Dirty (the cache area is in use) and sets the flag ON (step S170).

After that, the fixation of the 2nd Table 52 is performed in the memory system 1 (step S180). Specifically, the 2nd table migration control unit 13 writes the 2nd Table 52 from the cache memory 32 into the nonvolatile memory 20.

On the other hand, when the address updating unit 12 receives the physical address updating request 71 and when the address of the 2nd Table 52 that the 1st Table 51 indicates is in the cache memory 32 (in the cache memory in step S120), the address updating unit 12 reads the cache management table 53 based on the address of the 2nd Table 52 in the 1st Table 51 (step S190).

Then, the address updating unit 12 searches the cache management table 53 for the state value. This causes the address updating unit 12 to determine, based on the searched state value, which of the states the 2nd Table 52 is in (step S200).

When the state value is the Dirty (Dirty in step S200), the address updating unit 12 updates the physical address in the 2nd Table 52 that is in the cache memory 32 already (step S160). After that, the table updating unit 14 sets the state value in the cache management information 40 at the Dirty, and sets the flag ON (step S170). Furthermore, the fixation of the 2nd Table 52 is performed in the memory system 1 (step S180).

When the state value of the 2nd Table 52 is the Writing (Writing in step S200), the 2nd table migration control unit 13 searches the cache memory 32 for the space area (step S210).

Then, the 2nd table migration control unit 13 copies the latest 2nd Table 52 in the cache memory 32 (step S220). At that time, the 2nd table migration control unit 13 stores the copied latest 2nd Table 52 in the space area of the cache memory 32.

After the copying of the latest 2nd Table 52, the 2nd Table 52 in the copy source is not the latest 2nd Table 52. Thus, the table updating unit 14 turns OFF the flag stored in the cache management information 40 about the 2nd Table 52 in the copy source (step S230).

Then, the table updating unit 14 updates the address of the 2nd Table 52 in the 1st Table 51 (step S240). Specifically, the table updating unit 14 updates the address of the 2nd Table in the 1st Table 51 from the address of the copy source in the cache memory 32 to the address of the copy destination in the cache memory 32.

Then, the address updating unit 12 updates the physical address in the latest 2nd Table 52 in the cache memory 32 (step S160). After that, the table updating unit 14 sets the state value of the cache management information 40 at the Dirty, and sets the flag ON (step S170). Furthermore, the fixation of the 2nd Table 52 is performed in the memory system 1 (step S180).

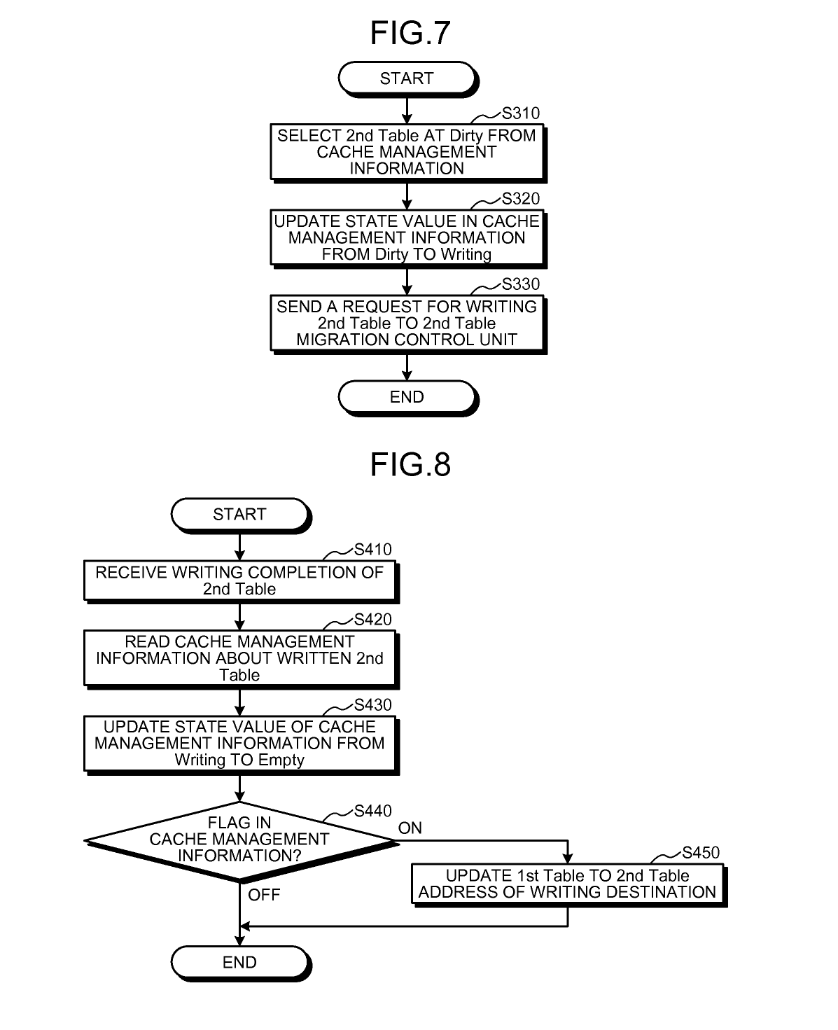

Then, FIG. 7 is a flowchart of the procedures in the process for the fixation of the 2nd Table. The table updating unit 14 selects the 2nd Table 52 of which state value is set at the Dirty in the cache management table 53 (step S310). Then, the table updating unit 14 updates the state value of the cache management information 40 about the selected 2nd Table 52 from the Dirty to the Writing (step S320). Furthermore, the table updating unit 14 sends a request for writing the 2nd Table 52 to the 2nd table migration control unit 13 (step S330). Accordingly, the 2nd table migration control unit 13 writes the 2nd Table 52 from the cache memory 32 into the nonvolatile memory 20. As a result, the 2nd Table 52 is fixed.

FIG. 8 is a flowchart of the procedures in the process for updating the cache management information. When receiving the writing completion notification 80 from the 2nd table migration control unit 13 (step S410), the table updating unit 14 searches the cache management table 53 to read the cache management information 40 about the written 2nd Table 52 (step S420).

The table updating unit 14 updates the state value in the read cache management information 40 to the Empty (step S430). Then, the table updating unit 14 confirms the flag of the cache management information 40 (step S440).

When the flag is set at ON (ON in step S440), the table updating unit 14 updates the 1st Table 51 (step S450). On the other hand, when the flag is set at OFF (OFF in step S440), the table updating unit 14 does not update the 1st Table 51.

As described above, the table updating unit 14 in the present embodiment updates the 1st Table 51 only when the flag is ON. In other words, the table updating unit 14 updates the 1st Table 51 using the address of the 2nd Table 52 in the nonvolatile memory 20 only when the 2nd Table 52 written into the nonvolatile memory 20 is the latest 2nd Table 52.

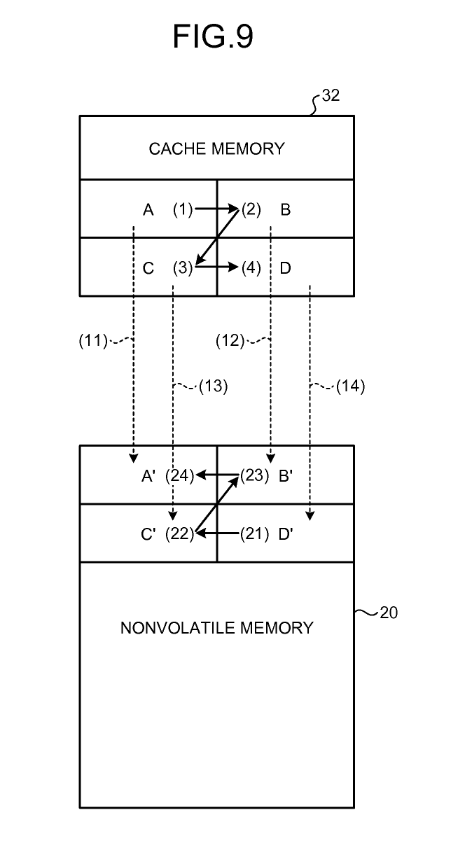

Next, the variations in the space area in the cache memory 32 when the 1st Table 51 is updated based on the flag of the cache management information 40 will be described. FIG. 9 is an explanatory diagram of the order in which the 2nd Tables are written from the cache memory to the nonvolatile memory. The case in which four 2nd Tables 52 are stored in the cache memory 32 and the four 2nd Tables 52 are written into the nonvolatile memory 20 will be described.

In FIG. 9, the first to fourth 2nd Tables 52 in the cache memory 32 are denoted by “A” to “D”, respectively. In FIG. 9, the first to fourth 2nd Tables 52 written into the nonvolatile memory 20 are denoted by “A′” to “D′”, respectively. Hereinafter, the 2nd Tables 52 will be referred to as the “A” to “D”, and “A′” to “D′”, respectively, in the description.

In FIG. 9, the “A′” is the “A” written into the nonvolatile memory 20. The “B′” is the “B” written into the nonvolatile memory 20. The “C′” is the “C” written into the nonvolatile memory 20. The “D′” is the “D” written into the nonvolatile memory 20.

In the memory system 1, for example, the “A” is read into the cache memory 32 (1), and the “A” is updated. After that, the writing of the “A” into the nonvolatile memory 20 is started (11).

In that case, when the host device 100 sends a Write request for writing the user data in process of writing the “A”, the “A” is copied and stored as the “B” in the cache memory 32 (2). Then, the “B” is updated and the writing of the “B” into the nonvolatile memory 20 is started (12).

Similarly, when the host device 100 sends a Write request for writing the user data while the “B” is in process of being written into the nonvolatile memory 20, the “B” is copied and stored as the “C” in the cache memory 32 (3). Then, the “C” is updated and the writing of the “C” into the nonvolatile memory 20 is started (13).

Similarly, when the host device 100 sends a Write request for writing the user data while the “C” is in process of being written into the nonvolatile memory 20, the “C” is copied and stored as the “D” in the cache memory 32 (4). Then, the “D” is updated and the writing of the “D” into the nonvolatile memory 20 is started (14).

In that case, the order in which the writings of the 2nd Tables 52 into the nonvolatile memory 20 are completed is sometimes different from the order in which the writings of the 2nd Tables 52 into the nonvolatile memory 20 has been started. This is because the 2nd table migration control unit 13 performs the control in a ch/bank parallel unit, or another process such as a reading request from the host device 100 interrupts the writing process. Thus, if the tables of the same logical address are updated in order of completion of the writings into the nonvolatile memory 20, there is a possibility that the 1st Table 51 indicates an old 2nd Table 52. In the present embodiment, updating the 1st Table 51 using the address of the latest 2nd Table 52 prevents the 1st Table 51 from indicating an old 2nd Table 52.

For example, it is assumed that the writings into the nonvolatile memory 20 are completed in order from the “D′”, the “C′”, the “B′”, to the “A′”. In other words, the writing of the “D′” is completed (21). After that, the writing of the “C′” is completed (22). After that, the writing of the “B′” is completed (23). After that, the writing of the “A′” is completed (24).

In the present embodiment in such a case, the 1st Table 51 is updated at the time when the writing of the “D′” is completed. Thus, the storage area of the “D” can be released from the cache memory 32 before the completion of the writings of the “C′” to “A′”.

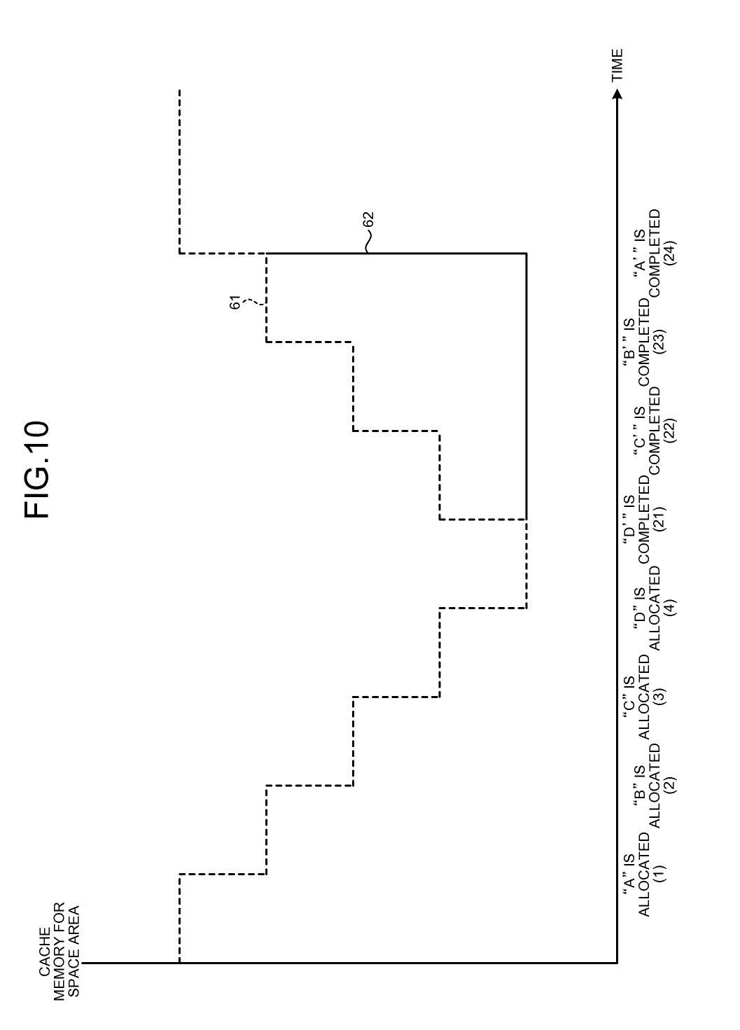

FIG. 10 is an explanatory diagram of the variations in the space area in the cache memory. The time is shown on the horizontal axis and the space area in the cache memory 32 is shown on the vertical axis in FIG. 10. Variation characteristic 62 illustrated in FIG. 10 is the variation characteristic when the areas that have stored the 2nd Tables 52 are released in order of reception of the writing requests. The variation characteristic 61 is the variation characteristic when the area that has stored the 2nd Table 52 based on the flag in the cache management information 40.

When the “A” is allocated to the cache memory 32, the space area in the cache memory 32 is reduced by the amount of the “A”. Similarly, when the “B” to “D” are allocated in order, the space area in the cache memory 32 is reduced by the amounts of the “B” to “D” in order. After that, when the writing of the “D′” is completed, the storage area of the “D” can be released from the cache memory 32.

The “D′” is the latest 2nd Table 52. Accordingly, the 2nd Tables 52 other than the “D′” are unnecessary. Specifically, the “A” to “D” are unnecessary. Thus, the “A” to “D” can be deleted from the cache memory 32 at the time when the “A′” to “D′” are written into the nonvolatile memory 20, respectively.

In the present embodiment, the table updating unit 14 can determine that the “D′” is the latest 2nd Table 52 by confirming the flag. Thus, in the memory system 1, when it is confirmed with the flag that the latest 2nd Table 52 has been written into the nonvolatile memory 20, the table updating unit 14 updates the 1st Table 51, and the 2nd table migration control unit 13 releases the storage area from the cache memory 32.

Specifically, when the writing of the “D′” is completed as illustrated on the variation characteristic 61 in FIG. 10, the 2nd table migration control unit 13 releases the area that has stored the “”D″ from the cache memory 32.

Similarly, when the writing of the “C′” is completed, the 2nd table migration control unit 13 releases the area that has stored the “”C″ from the cache memory 32. Similarly, when the writing of the “B′” is completed, the 2nd table migration control unit 13 releases the area that has stored the “”B″ from the cache memory 32. Similarly, when the writing of the “A′” is completed, the 2nd table migration control unit 13 releases the area that has stored the “”A″ from the cache memory 32.

On the other hand, when the areas that have stored the 2nd Tables 52 are released from the cache memory 32 in order of reception of the writing requests, the storage areas of the “”A″ to “”D″ are not released from the cache memory 32 as illustrated on the variation characteristic 62 until the “A′” is written into the nonvolatile memory 20.

Similarly, the storage areas of the “”B″ to “”D″ are not released from the cache memory 32 until the “B′” is written into the nonvolatile memory 20. Similarly, the storage areas of the “”C″ and “”D″ are not released from the cache memory 32 until the “C′” is written into the nonvolatile memory 20.

Thus, in the case of the variation characteristic 62, the space area remains small in the cache memory 32 until the writing of the “A′” is completed. In the present embodiment, the 2nd Tables 52 other than the latest 2nd Table 52 are released immediately after being written into the nonvolatile memory 20. This can increase the space area in the cache memory 32. In other words, the storage areas of the 2nd Tables 52 in the cache area of the cache memory 32 can be released in a small unit regardless of the order of the writing requests. This improves the turnover ratio of the cache area.

This can reduce the size of the cache memory 32 required for the update of the address conversion table. Furthermore, the flag is stored in a high-speed memory other than the 1st Table 51. This reduces the frequency of referring to or updating the 1st Table 51 that is often stored in a memory that is accessed at a low rate and has a large capacity. This can reduce adverse effects on the total performance of the memory system 1.

The 1st Table 51 is updated such that the 1st Table 51 indicates the latest 2nd Table 52. Thus, even when requests for updating the physical addresses of the same logical address are sent and the 2nd Tables 52 are separately fixed, the 1st Table 51 does not indicate an old 2nd Table 52 after the fixation. This secures a correct fixation of the 2nd Table 52. This can release the storage area from the cache memory 32 in order of completion of the writings regardless of the order of the writing requests. Thus, the storage area of the cache memory 32 can be reused in a short time. This can reduce the required size of the cache memory 32.

It is not necessary, when the 1st Table 51 is updated, to compare the address of the 2nd Table 52 in the cache memory 32 that has been written into the nonvolatile memory 20 with the address of the 2nd Table 52 that the 1st Table 51 indicates every time a writing is completed.

Note that, although the case in which the address updating unit 12 receives the physical address updating request 71 and determines whether the latest 2nd Table 52 is stored in the nonvolatile memory 20 is described in the present embodiment, the processes can be performed with the 2nd table migration control unit 13.

Although it is determined based on the flag in the present embodiment whether the 2nd Table 52 to be written into the nonvolatile memory 20 is the latest, it can be determined based on the information other than the flag whether the 2nd Table 52 is the latest.

Although the address conversion table in the present embodiment is a multistage type, the address conversion table is not necessarily a multistage type. Although the user data is transmitted from the host device 100 in the present embodiment, the user data can be transmitted from a device other than the host device 100.

The processes in steps S140 to S170 illustrated in FIG. 6 can be performed in any order as long as the process in step S140 is performed before the process in step S160. The processes in steps S220 to S240 illustrated in FIG. 6 can be performed in any order. The process in step S330 can be performed before the process in step S320 illustrated in FIG. 7. Furthermore, the processes in steps S440 and 5450 can be performed before the processes in steps S420 and 5430 illustrated in FIG. 8.

The cache management table storing unit 33 is not limited to an SRAM and can be another memory such as a DRAM. The 1st Table storing unit 31 can be a memory other than a DRAM. The cache memory 32 can be a memory other than an SRAM. The nonvolatile memory 20 can be a nonvolatile memory other than a NAND Flash ROM.

Although the multistage address conversion table in the present embodiment has a two-layer tree structure using the 1st Table 51 and the 2nd Table 52, the multistage address conversion table can have a n-layer tree structure from the first address conversion table to the nth (the n is a natural number equal to two or more) address conversion table.

The address conversion table is used for searching for the physical address using the logical address as the key. A table in which two or more tables are set between the logical address and the physical address is the multistage address conversion table. In the present embodiment, the 1st Table 51 is searched for the 2nd Table 52, and the 2nd Table 52 is searched for the physical address. Thus, a two-stage address conversion table is used in the present embodiment.

For example, the multistage address conversion table having a three-layer tree structure of the 1st Table, 2nd Table, and 3rd Table is described herein. In that case, the 1st Table indicates the address of the 2nd Table, the 2nd Table indicates the address of the 3rd Table, and the 3rd Table indicates the physical address.

The physical address is updated after the 2nd Table and 3rd Table are read from the nonvolatile memory 20 into the cache memory 32. Specifically, when the 3rd Table is read into the cache memory 32, or when the 3rd Table is copied in the cache memory 32, the 2nd Table is updated. Furthermore, the physical address of the 3rd Table is updated in the cache memory 32.

Alternatively, when the 2nd Table is read into the cache memory 32, or when the 2nd Table is copied in the cache memory 32, the 1st Table is updated. After that, the 3rd Table is written into the nonvolatile memory 20, for example, depending on the shortage in the cache memory 32. When the flag indicates that the 3rd Table to be written into the nonvolatile memory 20 is the latest, the 2nd Table is updated. When the 3rd Table is not the latest, the 2nd Table is not updated. The 3rd Table in the cache memory 32 that has been written into the nonvolatile memory 20 is released in the cache memory 32.

The 2nd Table is written into the nonvolatile memory 20, for example, depending on the shortage of the cache memory 32. When the flag indicates that the 2nd Table to be written into the nonvolatile memory 20 is the latest, the 1st Table is updated. When the 2nd Table is not the latest, the 1st Table is not updated. The 2nd Table in the cache memory 32 that has been written into the nonvolatile memory 20 is released in the cache memory 32.

As described above, the memory system 1 in the embodiment includes the multistage address conversion table including the 1st Table 51 and 2nd Table 52, the flag indicating whether the 2nd Table 52 is the latest, the nonvolatile memory 20, the cache memory 32, and the controller 10.

The controller 10 includes the 2nd table migration control unit 13, and the table updating unit 14. When the user data is transmitted from the host device 100, the 2nd table migration control unit 13 reads the 2nd Table 52 corresponding to the user data from the nonvolatile memory 20 into the cache memory 32, and the table updating unit 14 updates the read 2nd Table 52 in the cache memory 32.

The 2nd table migration control unit 13 further writes the updated 2nd Table 52 from the cache memory 32 into the nonvolatile memory 20. When the 2nd Table 52 corresponding to the user data is updated in process of the writing, the table updating unit 14 copies the updated 2nd Table 52 in the cache memory 32 and updated the copied 2nd Table 52.

When the writing is performed, the table updating unit 14 in the present embodiment determines based on the flag whether the 2nd Table 52 used for the writing is the latest. When determining that the 2nd Table 52 is the latest, the table updating unit 14 updates the 1st Table 51 and releases the storage area of the 2nd Table 52 used for the writing from the cache memory 32.

As described above, according to the embodiment, the memory system 1 determines based on the flag whether the 2nd Table 52 is the latest. Thus, it can be determined in a short time whether the 2nd Table 52 is the latest.

This can release the storage area from the cache memory 32 in a short time, and thus can suppress the decrease in the performance of the memory system 1 when the address conversion table is updated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
an address conversion table in which a logical address of user data transmitted from a host device is linked to a physical address indicating a storage position of the user data table, the address conversion table being include a first conversion table and a second conversion table storing the physical address and in which a storage position of the second conversion table is stored in the first conversion table;
a management table that stores first information for each of the second conversion tables, the first information indicating a state of the second conversion table;
a first memory that is nonvolatile and stores the user data, the address conversion table, and the management table;
a second memory that is volatile; and
a controller configured, after the user data is transmitted from the host device, to read the second conversion table corresponding to the user data from the first memory into the second memory and update the second conversion table in the second memory, and configured to write the updated second conversion table from the second memory into the first memory and configured, in the case where the controller updates the second conversion table corresponding to new user data while the writing, to copy the updated second conversion table in the second memory and update the second conversion table corresponding to the new user data,
wherein the controller performs the reading, the writing, and the copying, and the controller determines, after the writing is performed, whether the second conversion table is in a first state, the determination process being performed based on the first information
wherein, in the case where the second conversion table is determined to be in the first state, the controller is configured to update the first conversion table, and release a storage area of the second conversion table used for the writing.

2. The memory system according to claim 1, wherein, when updating the second conversion table in the second memory, the controller sets information indicating that the updated second conversion table is in the first state in the first information.

3. The memory system according to claim 1, wherein, when the second conversion table that is in process of being written from the second memory into the first memory is copied in the second memory, the controller sets information indicating that the second conversion table of a copy source is not in the first state in the first information.

4. The memory system according to claim 1, wherein, when the second conversion table that is in process of being written from the second memory into the first memory is copied in the second memory, the controller sets information indicating that the second conversion table of a copy destination is in the first state in the first information.

5. The memory system according to claim 1, further comprising:
a third memory configured to store the first conversion table read from the first memory when the first conversion table is updated; and
a fourth memory configured to store the management table read from the first memory when the management table is updated,
wherein the fourth memory is accessed at a higher rate than the third memory.

6. The memory system according to claim 1, wherein the controller updates an address indicating the storage position of the second conversion table in the first conversion table.

7. The memory system according to claim 1, wherein the controller updates the second conversion table that the controller has read or the second conversion table that the controller has copied in the second memory.

8. The memory system according to claim 7, wherein the controller updates the physical address in the second conversion table.

9. The memory system according to claim 1, wherein the management table further stores second information indicating a state of storage of the second conversion table for each of the second conversion tables, and the controller migrates the storage position of the second conversion table based on the second information.

10. The memory system according to claim 9, wherein the controller performs the copying when the second information indicates that the second conversion table corresponding to the user data is stored in the second memory and in process of being written into the first memory while the second conversion table is updated.

11. The memory system according to claim 9, wherein the controller reads the second conversion table corresponding to the user data from the first memory into the second memory and performs the copying when the second information indicates that the second conversion table corresponding to the user data is stored in the first memory while the second conversion table is updated.

12. The memory system according to claim 1, wherein the address indicating the storage position of the second conversion table is linked to the logical address in the first conversion table.

13. The memory system according to claim 1, wherein the address conversion table further includes a third conversion table in which a storage position of the first conversion table is linked to the logical address.

14. The memory system according to claim 5, wherein the second to fourth memories are accessed at a higher rate than the first memory.

15. The memory system according to claim 5, wherein the third memory is a DRAM, and the fourth memory is an SRAM.

16. The memory system according to claim 1, wherein the first memory is a NAND Flash ROM.

17. The memory system according to claim 1, wherein the second memory is an SRAM.

18. A memory system comprising:
an address conversion table in which a logical address of user data is linked to a physical address using a multistage conversion table that includes a first conversion table and a second conversion table and in which a storage position of the second conversion table is stored in the first conversion table;
management information that indicates whether the second conversion table is in the first state;
a first memory that is nonvolatile;
a second memory that is volatile; and
a controller configured to perform reading the second conversion table from the first memory into the second memory, writing the second conversion table from the second memory into the first memory, and copying the second conversion table in the second memory,;
wherein the controller updates the first conversion table and releases a storage area of the second conversion table used for the writing from the second memory in the case where determining based on the management information that the second conversion table used for the writing is in the first state.

19. A memory system comprising:
a first memory;
a second memory;
link information in which a logical address is linked to a physical address;
positional information indicating a position of the link information; and
a controller configured to update the positional information and update an area in which the link information used for the writing from the second memory is stored in the case where the link information written from the second memory into the first memory is in a first state.

20. A memory system comprising:
a first memory;
a second memory;
link information in which a logical address is linked to a physical address;
positional information indicating a position of the link information;
management information that indicates a state of the link information; and
a controller configured to update the positional information and update an area in which the link information used for the writing from the second memory is stored in the case where determining based on the management information that the link information written from the second memory into the first memory is in a first state.
